(19) United States
(12) Patent Application Publication
(10) Pub. No.: US 2010/0055442 A1
(43) Pub. Date: Mar. 4, 2010

(54) METHOD OF PE-ALD OF SiNxCy AND INTEGRATION OF LINER MATERIALS ON POROUS LOW K SUBSTRATES

(75) Inventors: Andrew J. Kellock, Sunnyvale, CA (US); Hyungjun Kim, Pohang (KR); Dae-Gyu Park, Poughquaq, NY (US); Satyanarayana V. Nitta, Poughquag, NY (US); Sampath Purushothaman, Yorktown Heights, NY (US); Stephen Rossnagel, Pleasantville, NY (US); Oscar Van Der Straten, Mohegan Lake, NY (US)

Correspondence Address: Connolly Bove Lodge & Hutz LLP, Suite 1100, 1875 Eye Street, NW, Washington, DC, 20006, US

(73) Assignee: International Business Machines Corporation, Armonk, NY (US)

(21) Appl. No.: 12/203,338

(22) Filed: Sep. 3, 2008

(51) Int. Cl. C23C 16/513; B32B 3/26

(52) U.S. Cl. 428/319.1; 427/577

(57) ABSTRACT

A method of depositing a SiNₓC_{y} liner on a porous low thermal conductivity (low-k) substrate by plasma-enhanced atomic layer deposition (PE-ALD), which includes forming a SiNₓC_{y} liner on a surface of a low-k substrate having pores on a surface thereon, in which the low-k substrate is repeatedly exposed to a aminosilane-based precursor and a plasma selected from nitrogen, hydrogen, oxygen, helium, and combinations thereof until a thickness of the liner is obtained, and wherein the liner is prevented from penetrating inside the pores of a surface of the substrate. A porous low thermal conductivity substrate having a SiNₓC_{y} liner formed thereon by the method is also disclosed.

### BACKGROUND

1. Technical Field

The disclosure generally relates to a method for depositing liner materials on porous low temperature substrates by plasma enhanced atomic layer deposition (PE-ALD). In particular, a SiNₓC_{y} liner is formed on a porous low dielectric constant (low-k) substrate by PE-ALD, without any penetration of the pores of the surface of the substrate. The method provides the deposition of a liner that prevents pore penetration of a low-k material.

2. Discussion of the Background

Materials have been developed and studied for reducing the dielectric constant of dielectrics for back end of the line (BEOL) processes and similar processes. One of the promising candidates of materials for this purpose is porous low dielectric constant (low-k) materials. These dielectrics may include porous low-k materials, such as SiCO, and spin-on dielectrics, including porous SiLK™, a low-k dielectric resin (a trademark of Dow Chemical Company, and JSR LKD 5109™, a low-k dielectric material containing Si, C, O, and H (a trademark of JSR Micro, Inc.). However, there are several issues to be solved in implementing these materials.

A major concern in industry is the penetration of liner materials, such as tantalum nitride (TaN), into the pores of such dielectric low-k materials, when the liners are deposited by various methods including chemical vapor deposition (CVD) and atomic layer deposition (ALD). In particular, ALD has become a more promising technique than CVD to deposit liners for various technologies, due to its ability to produce highly conformal films. However, the extremely good conformality of the technique causes easier penetration to the inside pores of porous low-k materials. Further, surface treatment, including plasma treatment, only produces partial success by sealing these surface pores.

Another concern is that the performance in advanced microelectronic chips has become more and more limited by the signal propagation delay in interconnect wiring on these chips. This delay is a function of the electrical resistance of the wires and the effective capacitance resulting from the dielectric medium surrounding the wires. It has been found that the replacement of aluminum (Al) wires with lower resistivity copper (Cu) wires enables the reduction of the interconnect resistance, and the reduction of effective interconnect capacitance may be achieved through the use of lower dielectric constant (k) insulators between interconnect wires. In particular, one efficient way to lower the k value of insulators has been to use porous dielectrics. In particular, k values as low as 1.4 have been achieved by starting with a fully dense insulator with a k value of about 2.7, for example spin-on glass films of the silsesquioxane type, and introducing up to about 55%-60% porosity. However, current ALD of metal liners results in severe penetration into nano pores of porous low-k materials.

Strategies to prevent this penetration has been studied and developed. One strategy has been the use of thin protective layer, preferably low-k materials. However, the use of spin-on techniques does not provide conformal coating to high aspect ratio dual damascene structures. Therefore, in view of the foregoing, there remains a need for a technique to deposit a liner that prevents pore penetration of a low-k material.

This disclosure provides a plasma-enhanced ALD (PE ALD) of SiNₓC_{y}, as a protective layer for consecutive deposition of metal liners without penetration.

### SUMMARY OF THE DISCLOSURE

Accordingly, the following aspects provide a method for employing plasma enhanced atomic layer deposition (PE-ALD) to deposit a SiNₓC_{y} liner on various porous low-k materials. In particular, during PE-ALD, the surface of porous low-k materials is exposed to plasma for the several initial cycles. Since the plasma effectively seals the surface of the pores, real time pore sealing occurs through the deposition.

In one aspect, the method of depositing the SiNₓC_{y} liner by PE-ALD comprises: forming a SiNₓC_{y} liner on a surface of a low-k substrate having pores on a surface thereon,

wherein y+z ranges from about 0.8 to 1.2,

wherein the low-k substrate is repeatedly exposed to a aminosilane-based precursor and a nitrogen or hydrogen plasma until a thickness of the liner is obtained, and

wherein the liner is prevented from penetrating inside the pores of a surface of the substrate.

In another aspect, the disclosure provides a method in which a protective layer is first formed on the low-k material substrate by PE-ALD from the aminosilane-based precursor and a nitrogen plasma, and then a substantially stoichiometric SiNₓC_{y} layer is formed by PE-ALD from the aminosilane-based precursor and a plasma consisting of hydrogen and nitrogen.

In a further aspect, the disclosure provides a porous low-k substrate having a SiNₓC_{y} liner formed thereon according to above method, without penetration of pores on a surface of the substrate.

Still other objects and advantages of the present disclosure will become readily apparent by those skilled in the art from the following detailed description, wherein it is shown and described only in the preferred embodiments, simply by way of illustration of the best mode. As will be realized, the disclosure is capable of other and different embodiments, and its several details are capable of modifications in various obvious respects, without departing from the intent of this disclosure. Accordingly, the description is to be regarded as illustrative in nature and not as restrictive.

### BRIEF DESCRIPTION OF THE DRAWINGS

FIG. 1 shows a graphic illustration of the growth rate of PE-ALD SiNxCy determined by Rutherford Backscattering Spectrometry (RBS).

FIG. 2 shows a graphic illustration of the chemical composition of ALD SiNxCy as a function of growth temperature.

FIG. 3 shows a cross-sectional transmission electron microscopy (TEM) image for TaN/SiNxCy/TaN, deposited by PE-ALD on patterned porous low-k materials.

### BEST AND VARIOUS MODES FOR CARRYING OUT THE DISCLOSURE

A more complete appreciation of the disclosure and many of the attendant advantages will be readily obtained, as the same becomes better understood by reference to the following detailed description when considered in connection with the accompanying figures.

In the method of the disclosure, a number of cycles may be repeated in accordance with the PE-ALD technique. In one embodiment, the method is carried out in a noncommercial ALD chamber capable of handling sample sizes as large as 200 mm diameter. The chamber may include a reactive-gas grade turbo molecular pump with a working base pressure of 10⁻⁷ Torr. Sample heating may be conducted using a ceramic resistive heating plate, which provides growth temperatures up to 450° C. The heating, in one embodiment, runs at approximately 300° C. The temperature may be controlled by varying current to the heater, which may be calibrated against a thermocouple attached to the sample.

Due to the recombination and/or deactivation of reactive species for PE-ALD on porous surfaces of low-k substrates, including the inside surface of pores, the conformality of liners by PE-ALD generally includes nano scale pores, though the conformality of liner is sufficient for depositing desired liners inside the trenches and vias. Thus, the penetration of liners during PE-ALD is further minimized. In addition, the in situ surface treatment by plasma inside the deposition chamber can further minimize the penetration for certain low-k materials. Since the deposition chamber has built-in plasma comparability, no extra surface treatment chamber is required.

Generally, a SiNₓC_{y} liner may be formed on a porous low-k material substrate, which may be a patterned porous low-k substrate, by PE-ALD from a aminosilane-based precursor and a plasma. In the formula of SiNₓC_{y}, y+z is within the range of about 0.8 to 1.2, preferably approaching 1, in which x may equal about from 0.01 to 0.99 and y may equal about from=0.99 to 0.01.

The low-k substrate is exposed to an aminosilane-based precursor. A precursor which has been investigated for the silylation of low-k materials is bis(dimethylamino)dimethylsilane (BDMA-DMS). The chemical structure of the precursors is very similar to that of pentakis(dimethylamino)tantalum, which is a metal organic precursor used for ALD of tantalum nitride (TaN) liners. However, this disclosure is not limited to BDMA-DMS precursor or other aminosilanes, and may include other silylation (silylating) agents with a similar structure as ALD precursors for the process. For instance, silylation agents that may be used include, but are not limited to, mono-, di-, or tri-alkoxy(alkyl)silanes, chloro(alkyl)silanes, bromo (alkyl) silanes, thiocyanate(alkyl) silanes, phosphonates or combinations thereof.

In a preferred embodiment, the PE-ALD method, in accordance with this disclosure, has been developed from the reaction of BDMA-DMS and atomic hydrogen.

The glass tube may be maintained at 65° C. to develop adequate vapor pressure and all the delivery lines were heated to 80° C. to prohibit condensation of the precursor. To improve the delivery of the aminosilane-based precursor, a carrier gas including, e.g., argon (Ar), may be used, the flow of which may be controlled by a mass flow controller upstream from the source tube. In one embodiment, the substrate is exposed to >1000 Langmuirs (L) of aminosilane carried by Ar gas. It should be understood that a Langmuir equals exposure for is at 10⁻⁶ Torr. The chamber may be evacuated, e.g., using an evacuation pump.

In one embodiment, no purging gas is used between metal precursor and plasma exposure. However, it should be understood that a purging gas may be used, which should not change the result of the method.

Substrates upon which the method may be implemented include any low-k material, which may include but is not limited to, silicon dioxide (SiO₂), hydro-fluoric (HF) dipped silicon (Si), JSR LKD 5109™ or a similar material, nanoglass, SiCO, and SiLK™.

A hydrogen (atomic hydrogen), oxygen, nitrogen, helium, or combination thereof plasma may be used to treat the above-mentioned porous low-k materials before ALD.

In another embodiment, the low-k substrate is exposed to nitrogen plasma. In this embodiment, a gate valve for nitrogen is opened for a radio frequency (RF) source. The RF plasma source may be any conventional plasma source including, for example, a quartz tube wrapped with copper (Cu) coil for producing the plasma. PE-ALD from the aminosilane-based precursor in the hydrogen results in the formation of the SiNₓC_{y} liner or a protective layer.

For JSR LKD 5109™, nanoglass, and SiCO porous low k materials, BDMA-DMS and atomic hydrogen produced by plasma may be used to deposit SiNₓC_{y} by PE-ALD. For porous SiLK™, since the atomic hydrogen etches the SiLK™ substrates, nitrogen plasma has been used instead. After 10 to 50 cycles of nitrogen plasma based process, the plasma gas may be switched to hydrogen and deposition to desired thickness has been done. In a separate embodiment, the chamber may be evacuated again and one cycle of PE-ALD to form the SiNₓC_{y} liner is completed. A number of cycles may be repeated, which determines the thickness of the liner or protective layer.

Next, a subsequent substantially stoichiometric SiNₓC_{y} diffusion barrier layer may be formed by PE-ALD from the aminosilane-based precursor and a plasma of hydrogen and nitrogen. This step may be repeated for a number of cycles, which determines the thickness of the substantially stoichiometric SiNₓC_{y} diffusion barrier layer. For instance, the number of cycles employed may be 100 cycles for the protective layer and 800 cycles for substantially stoichiometric SiNₓC_{y} diffusion barrier layer.

In another embodiment, the initial or protective layer(s) may be TaN deposited by PE-ALD, in which a subsequent substantially stoichiometric SiNₓC_{y} diffusion barrier layer by PE-ALD may be formed on the TaN, and an additional TaN layer deposited on the diffusion barrier layer. In other words, the SiNC layer may be deposited between PE-ALD of TaN, such that TaN/SiNxCy/TaN may be formed.

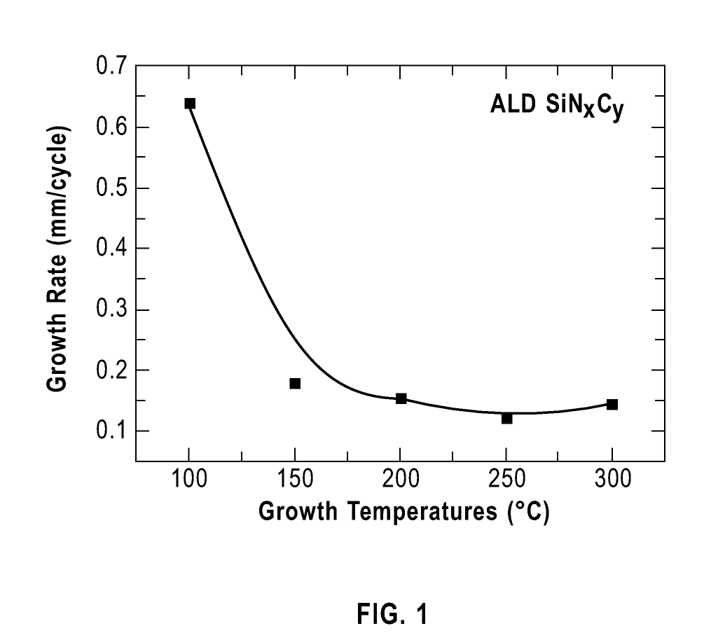

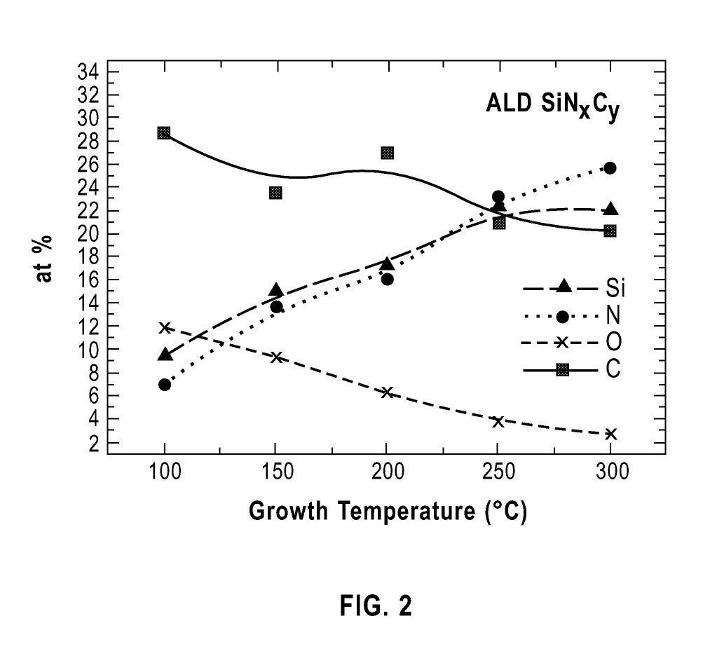

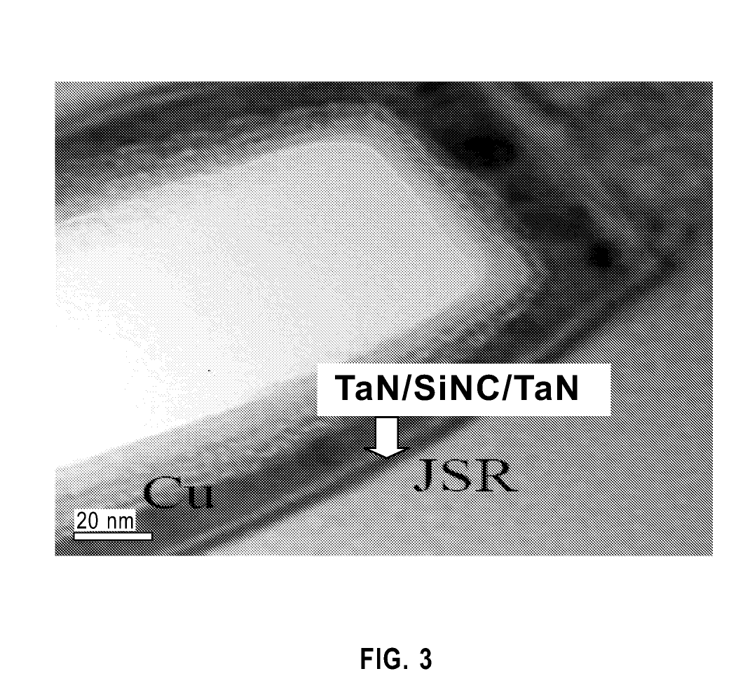

Turning to the non-limiting illustrations of the disclosure, film layers were prepared according to the method and analyzed by Rutherford Backscattering Spectrometry (RBS). As shown in FIG. 1, high growth rate over 0.1 nm/cycle was achieved as low temperature as 150° C. The chemical composition analysis shows, in FIG. 2, that the film is composed of Si, N, and C, which is a general composition of low-k or dielectric hard mask currently used in a semiconductor process. In FIG. 3, a transmission electron microscopy (TEM) image, the SiNC layer deposited between PE-ALD of TaN layers shows that the conformality of the film is good. By using this method, the pores on the surfaces of porous low-k materials is sealed off, preventing further liner penetration by following liner deposition by ALD and CVD methods.

Obviously, numerous modifications and variations of the disclosure are possible in light of the above disclosure. It is therefore understood that within the scope of the appended claims, the disclosure may be practiced otherwise than as specifically described herein.

What is claimed is:

1. A method of depositing a SiNₓC_{y} liner on a porous low dielectric constant (low-k) substrate by plasma-enhanced atomic layer deposition (PE-ALD), the method comprising:
forming a SiNₓC_{y} liner on a surface of a low-k substrate having pores on a surface thereon,
wherein y+z ranges from about 0.8 to 1.2,
wherein the low-k substrate is repeatedly exposed to a tantalum-based precursor and a plasma selected from the group consisting of nitrogen, hydrogen, oxygen, helium, and combinations thereof until a thickness of the liner is obtained, and
wherein the liner is prevented from penetrating inside the pores of a surface of the substrate.

2. The method according to claim 1, wherein the aminosilane precursor is a silylation agent selected from the group consisting of aminosilanes, mono-, di-, or tri-alkoxy(alkyl)silanes, chloro(alkyl)silanes, bromo (alkyl) silanes, thiocyanate(alkyl) silanes, phosphonates or combinations thereof.

3. The method according to claim 1, wherein the aminosilane precursor is bis(dimethylamino)dimethylsilane (BDMA-DMS).

4. The method according to claim 1, wherein the porous low-k substrate is selected from the group consisting of silicon dioxide (SiO₂), hydro-fluoric (HF) dipped silicon (Si), nanoglass, SiCO, dielectric resin, and a spin-on dielectric material.

5. The method according to claim 1, wherein the porous low-k substrate is a dielectric resin.

6. The method according to claim 1, wherein the plasma is hydrogen.

7. The method according to claim 1, wherein the plasma is nitrogen.

8. The method according to claim 1, wherein the substrate the low-k material substrate is exposed for greater than 1000 Langmuirs.

9. The method according to claim 1, wherein the aminosilane precursor is carried by an inert gas.

10. The method according to claim 9, wherein the inert gas is argon.

11. The method according to claim 1, wherein the deposition temperature ranges from about 150 to about 450° C.

12. The method according to claim 1, wherein the deposition temperature ranges from about 150 to about 300° C.

13. The method according to claim 1, wherein the deposition temperature is 250° C.

14. The method according to claim 1, wherein the low-k substrate is exposed to the tantalum-based precursor and a nitrogen or hydrogen plasma for about 10 to about 800 cycles.

15. The method according to claim 1, wherein y+z equals 1.

16. The method according to claim 1, wherein the plasma consists of hydrogen and nitrogen.

17. The method according to claim 16, wherein a substantially stoichiometric SiNₓC_{y} is formed from the aminosilane-based precursor and the plasma.

18. The method according to claim 1, wherein a protective layer is first formed on the low-k material substrate by the PE-ALD from the aminosilane-based precursor and a hydrogen plasma, and then a substantially stoichiometric SiNₓC_{y} layer is formed by the PE-ALD from the aminosilane-based precursor and a plasma consisting of hydrogen and nitrogen.

19. The method according to claim 18, wherein SiNₓC_{y} is deposited between one or more layers of tantalum-nitride.

20. A porous low thermal conductivity substrate having a SiNₓC_{y} liner formed thereon by the method according to claim 1, without penetration of pores on a surface of the substrate.
